(19) United States
(12) Patent Application Publication
(10) Pub. No.: US 2007/0200149 A1
(43) Pub. Date: Aug. 30, 2007

(54) Semiconductor device and method of production

(76) Inventors: Veronika Polei, Dresden (DE); Dominik Olligs, Dresden (DE)

Correspondence Address: SLATER & MATSIL LLP, 17950 PRESTON ROAD, SUITE 1000, DALLAS, TX, 75252, US

(21) Appl. No.: 11/364,586

(22) Filed: Feb. 28, 2006

(51) Int. Cl. H01L 29/80

(52) U.S. Cl. 257/267

(57) ABSTRACT

A layer sequence with lateral boundaries, especially a gate electrode stack, comprises a cover layer between a metal layer and a top layer that is provided as a hardmask. The cover layer, which is preferably polysilicon, enables the application of a cleaning agent to remove a resist layer, clean the hardmask and remove deposits of the material of the top layer produced in the structuring of the hardmask, before the layer sequence is structured using the hardmask. The cover layer protects the metal layer, which could otherwise be damaged by the cleaning agent.

### TECHNICAL FIELD

This invention concerns semiconductor devices, especially devices comprising gate electrode stacks, and a method of production.

### BACKGROUND

Semiconductor devices with integrated transistor structures are provided with gate electrodes and conductor tracks for an electric connection of the gate electrode. The gate electrode and conductor track are preferably structured as a gate stack, which usually comprises several electrically conductive layers. The gate electrode is arranged above the channel region of the transistor and separated from the semiconductor material by a thin gate dielectric. The gate electrode can be formed of a polysilicon layer, which is electrically conductively doped. Since the track resistance of the polysilicon is too large, the polysilicon layer is doubled with a metal or metal silicide layer. The metal provides a better electric conductivity.

The gate electrode stack is structured by means of a hardmask. A photolithography technique using a structured resist layer is applied to structure a layer of a suitable material, for instance nitride, to form the hardmask. The resist is removed after the hardmask has been structured. The hardmask is cleaned with a cleaning agent. In some cases, it cannot be avoided that the hardmask is superficially damaged by the cleaning agent, which solves small particles out of the hardmask without completely removing them. Although the material of the hardmask is not actually attacked and dissolved, the application of the cleaning agent may nevertheless lead to tiny deposits of the hardmask material on other surfaces of the device, where they form micromasks that affect further processing steps unfavorably. If an even stronger cleaning agent, which dissolves the particles that have come out of the hardmask, especially nitride particles, is applied, such a cleaning agent may also attack the metal layer, which is laid bare in the openings of the hardmask.

### SUMMARY OF THE INVENTION

In one aspect, this invention provides a way to avoid undesired deposits that are produced when a hardmask is treated with a cleaning agent.

In a further aspect, this invention provides a device structure that includes a metal being structured by a hardmask and that allows for a cleaning of the hardmask with a cleaning agent that attacks the metal.

In still a further aspect, this invention provides the device structure as a gate electrode stack.

In another aspect, this invention provides a method for producing a stack of layers including a metal, which is structured by means of a hardmask, by which the hardmask is cleaned without producing undesired deposits.

In a further aspect, this invention provides a method for producing a gate electrode stack with a metal layer that is structured by a hardmask, by which the hardmask can be cleaned with a cleaning agent that attacks the metal.

In a first embodiment, a semiconductor device includes a structured layer sequence with lateral boundaries including at least a metal layer and a cover layer above the metal layer. The material of the cover layer is different from the metal. In preferred embodiments, a top layer formed of a material that is suitable for hardmasks is arranged on the cover layer. The layer sequence can be provided for a gate electrode stack and comprise further layers. The typical embodiment of this device comprises a transistor structure, a gate dielectric, a gate layer, preferably of doped polysilicon, a metal layer, a cover layer, and a hardmask layer forming the top layer. The metal layer can be tungsten, for example, the cover layer can be polysilicon, and the top layer can be nitride. There are preferably thin liners on the upper and lower boundary surfaces of the metal layer.

The production method comprises a cleaning step that makes use of a cleaning agent that also removes deposits of the material of the top layer, which can especially be nitride. The cleaning agent can especially be an aqueous solution of H₂O₂ and NH₃. This cleaning agent is appropriate to remove the rest of the photoresist and small particles of nitride. It attacks the metal but does not attack the metal layer, because the metal layer is protected by the cover layer. This method enables the application of cleaning agents that are especially suitable to clean hardmasks, especially nitride hardmasks, but would attack the metal layer of the gate electrode stack.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross section of a typical layer sequence provided for a gate electrode stack before the structuring by means of a hardmask; and

FIG. 2 shows the cross section according to FIG. 1 after the structuring of the stack.

The following list of reference symbols can be used in conjunction with the figures:
1 substrate
2 gate dielectric
3 further layer
4 liner
5 metal layer
6 liner
7 cover layer
8 top layer
9 sidewall insulation

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

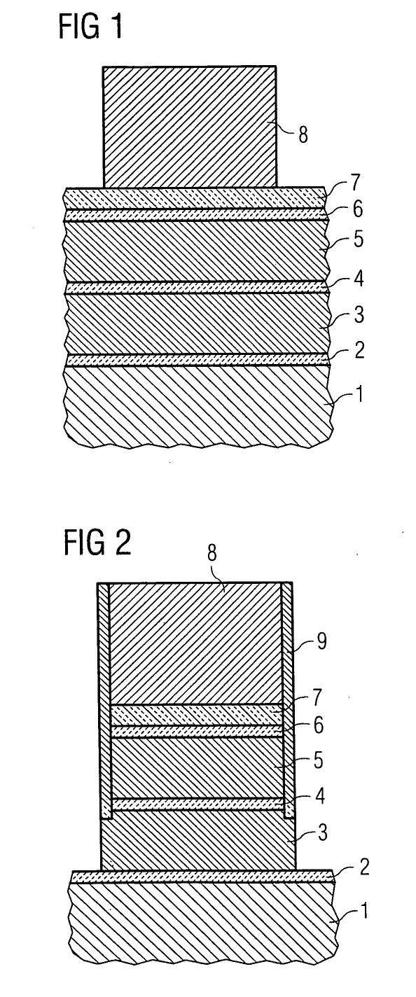

FIG. 1 shows a cross section through a layer sequence that is intended for a gate electrode stack. On a main surface of a substrate 1 a gate dielectric 2 is applied on a region that is provided for a transistor channel. A further layer 3 forms the gate electrode and is preferably electrically conductively doped polysilicon. On this further layer 3 a liner 4 is applied to separate the polysilicon from the metal layer 5 above. The liner prevents a silicidation of the metal. The metal can be tungsten and is provided to reduce the track resistance of the stack.

A further liner 6, not present in usual gate stacks, is applied on the upper boundary surface of the metal layer 5. The liner 6 separates the metal from the material of a cover layer 7, which is preferably polysilicon. The cover layer 7 can be electrically conductive or not. The top layer 8, which can be silicon nitride, is provided for a hardmask and can be structured by a photolithography step using a resist mask.

After the hardmask has been structured from the top layer 8, the resist mask is preferably removed. This can be done by means of a plasma, by which the resist is transformed into ashes. The ashes are removed by a subsequent cleaning step using a wet chemical solution. This is usually done with a cleaning agent comprising H₂SO₄, O₃ and H₂O₂. This solution also solves small particles out of the top layer 8, but does not totally dissolve them. The particles settle on various locations on the substrate and form tiny masks, which affect the further process steps.

The structure shown in FIG. 1 enables the use of a cleaning agent that removes not only the residues of the resist but also any undesired deposits of the material of the top layer 8. A suitable cleaning agent is, for example, an aqueous solution of H₂O₂ and NH₃. This solution attacks metal by oxidation. Therefore, it cannot be used in the cleaning step if there are free surfaces of the metal layer. The provided cover layer 7 enables the application of cleaning agents that are preferred as they avoid deposits of the material of the top layer 8, but could not be used in conjunction with open metal layers.

The upper liner 6 is optional, but is preferred if the cover layer 7 is polysilicon. In this case, the liner 6 inhibits a silicidation of the metal layer in further processing steps at elevated temperature. If the metal layer 5 is tungsten, the liner can comprise WN and Ti, as one example.

FIG. 2 shows the cross section according to FIG. 1 after the structuring of the gate electrode stack. The structured top layer 8 has been used as a hardmask to etch the layer sequence into striplike conductor tracks. The sidewall insulations 9 that cover the sidewalls of the stack, at least in the area of the metal layer 5, are preferably formed from the same material as the top layer, preferably nitride. Different from the usual gate electrode stack, which comprises a polysilicon layer, a metal layer or metal silicide layer and a nitride encapsulation, the gate electrode stack according to FIG. 2 comprises a metal layer that is arranged within layers of a different material, preferably polysilicon, and the encapsulation is applied onto the cover layer.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, methods and steps described in the specification. As one of ordinary skill in the art will readily appreciate from the disclosure of the present invention, processes, machines, manufacture, compositions of matter, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, methods, or steps.

What is claimed is:

1. A semiconductor device, comprising:
a body of semiconductor material having a main surface; and
at least one metal layer over the main surface and a conductive cover layer above said at least one metal layer, said conductive cover layer being a material that is different from said at least one metal layer; wherein the at least one metal layer and the conductive cover layer form a layer sequence that is structured with lateral boundaries.

2. The semiconductor device according to claim 1, further comprising a hardmask layer overlying the conductive cover layer.

3. The semiconductor device according to claim 1, further comprising a nitride layer above said conductive cover layer.

4. The semiconductor device according to claim 1, wherein the conductive cover layer comprises a semiconductor material.

5. The semiconductor device according to claim 4, wherein the conductive cover layer comprises polysilicon.

6. The semiconductor device according to claim 1, wherein the at least one metal layer comprises tungsten.

7. The semiconductor device according to claim 1, further comprising a further layer, such that said at least one metal layer is arranged between said further layer and said conductive cover layer.

8. The semiconductor device according to claim 7, wherein the further layer comprises a semiconductor material.

9. The semiconductor device according to claim 8, wherein the further layer comprises polysilicon.

10. The semiconductor device according to claim 9, further comprising a gate dielectric between said at least one metal layer and said main surface of said body, such that the layer sequence comprises a gate electrode of a transistor structure.

11. A semiconductor device, comprising:
a region of semiconductor material;
a gate electrode over the semiconductor material, the gate electrode comprising a layer sequence that includes at least a metal layer, a cover layer over said metal layer, and a top layer over said cover layer;
a gate dielectric between the gate electrode and the semiconductor material; and
doped regions in the semiconductor material adjacent the gate electrode.

12. The semiconductor device according to claim 11, wherein the cover layer is a material that is different from the at least one metal layer.

13. The semiconductor device according to claim 11, wherein the cover layer comprises a semiconductor material.

14. The semiconductor device according to claim 11, wherein the cover layer comprises polysilicon.

15. The semiconductor device according to claim 11, wherein the metal layer comprises tungsten.

16. The semiconductor device according to claim 11, wherein the top layer comprises a material that is suitable for a hardmask.

17. The semiconductor device according to claim 11, wherein the top layer comprises a nitride.

18. A semiconductor device comprising:
a semiconductor body;
a metal layer overlying the semiconductor body;
a liner overlying the metal layer; and
a polysilicon layer overlying the liner;
wherein the metal layer, the line and the polysilicon layer are electrically coupled together and structured to form a conductive electrode.

19. The device of claim 18, further comprising a second polysilicon layer between the semiconductor body and the metal layer, the second polysilicon layer structured to be a part of the conductive electrode.

20. The device of claim 19, further comprising a second liner between the second polysilicon layer and the metal layer.

21. The device of claim 20, wherein the metal layer comprises tungsten.

22. The device of claim 18, further comprising a hardmask layer overlying the polysilicon layer, the hardmask layer being structured in the pattern of the conductive electrode.

23. A method of fabricating a semiconductor device, the method comprising:
providing a substrate with a main surface;
applying a layer sequence over said main surface, said layer sequence comprising at least a metal layer and a cover layer over the metal layer;
applying a top layer from a material that is suitable for hardmasks over the cover layer;
structuring the top layer to form a hardmask; and
cleaning the hardmask with a cleaning agent.

24. The method according to claim 23, wherein structuring the top layer comprises using a resist.

25. The method according to claim 24, wherein cleaning the hardmask comprises selecting the cleaning agent to remove residues of said resist.

26. The method according to claim 23, wherein cleaning the hardmask comprises selecting the cleaning agent to remove deposits that are produced in the structuring of the hardmask.

27. The method according to claim 23, wherein the cleaning agent comprises an aqueous solution of H₂O₂ and NH₃.

28. The method according to claim 23, wherein applying a top layer comprises forming a nitride layer.

29. The method according to claim 23, wherein the cover layer comprises polysilicon.

30. The method according to claim 27, wherein the hardmask comprises nitride, and the cover layer comprises polysilicon.
